(19) United States
(12) Patent Application Publication
(10) Pub. No.: US 2023/0314633 A1
(43) Pub. Date: Oct. 5, 2023

(54) RADIATION DETECTION MODULE AND MANUFACTURING METHOD FOR RADIATION DETECTION MODULE

(71) Applicant: Sharp Display Technology Corporation, Kameyama City (JP)

(72) Inventors: Wataru NAKAMURA, Kameyama City (JP); Akinori KUBOTA, Kameyama City (JP); Yu NAKAMURA, Kameyama City (JP)

(21) Appl. No.: 18/128,219

(22) Filed: Mar. 29, 2023

(30) Foreign Application Priority Data
Mar. 31, 2022 (JP) 2022-060818

(51) Int. Cl. G01T 1/20; H01L 27/146

(52) U.S. Cl. CPC G01T 1/2018; H01L 27/14663; H01L 27/14683

(57) ABSTRACT

A radiation detection module includes an active matrix substrate and a scintillator. The active matrix substrate includes a support substrate including a first main surface, the first main surface including a first region and a second region surrounding the first region, and a plurality of pixels one-dimensionally or two-dimensionally arrayed in the first region of the first main surface, the plurality of pixels each of which includes a switching element and a photoelectric conversion element electrically connected to the switching element. The scintillator covers the photoelectric conversion elements of the plurality of pixels. A thickness of the support substrate in the first region is smaller than a thickness in the second region.

### CROSS-REFERENCE TO RELATED APPLICATIONS

This application claims the benefit of priority to Japanese Patent Application Number 2022-060818 filed on Mar. 31, 2022. The entire contents of the above-identified application are hereby incorporated by reference.

### BACKGROUND

### Technical Field

The disclosure relates to a radiation detection module and a manufacturing method for the radiation detection module.

With the development of image processing techniques, various image diagnostic apparatuses are widely used also in the medical field. In a diagnostic apparatus using radiation such as X-rays, a radiation Flat Panel Detector (FPD) capable of directly converting radiation transmitted through a body or an object into digital data is used. For example, JP 2011-17683 A discloses such an FPD.

### SUMMARY

An object of the disclosure is to provide a radiation detection module capable of acquiring a radiation image with higher sensitivity and higher resolution and a manufacturing method for the radiation detection module.

A radiation detection module according to an embodiment of the disclosure includes an active matrix substrate including a support substrate including a first main surface and a second main surface positioned at an opposite side to the first main surface, the first main surface including a first region and a second region surrounding the first region, and a plurality of pixels one-dimensionally or two-dimensionally arrayed in the first region of the first main surface, the plurality of pixels each of which includes a switching element and a photoelectric conversion element electrically connected to the switching element, and a scintillator covering the photoelectric conversion elements of the plurality of pixels, and a thickness of the support substrate in the first region is smaller than a thickness of the support substrate in the second region.

According to the embodiment of the disclosure, there are provided a radiation detection module capable of acquiring a radiation image with higher sensitivity and higher resolution and a manufacturing method for the radiation detection module.

### BRIEF DESCRIPTION OF DRAWINGS

The disclosure will be described with reference to the accompanying drawings, wherein like numbers reference like elements.

FIG. 1 is a schematic plan view illustrating a configuration of a radiation detection module according to the present embodiment.

FIG. 2 is a cross-sectional view of the radiation detection module taken along a line II-II in FIG. 1.

FIG. 3 is a cross-sectional view of a support substrate.

FIG. 4 is a schematic view illustrating a circuit configuration of the radiation detection module.

FIG. 5 is a cross-sectional view illustrating an example of a structure of a pixel.

FIG. 6 is a schematic view for describing an operation of the radiation detection module.

FIG. 7 is a diagram showing a transmittance of X-rays with respect to a thickness of glass.

FIG. 8 is a flowchart illustrating a manufacturing method for the radiation detection module according to the present embodiment.

FIG. 9 is a flowchart illustrating another example of the manufacturing method for the radiation detection module according to the present embodiment.

FIG. 10A is a cross-sectional view of one process in the manufacturing method for the radiation detection module according to the present embodiment.

FIG. 10B is a cross-sectional view of one process in the manufacturing method for the radiation detection module according to the present embodiment.

FIG. 10C is a cross-sectional view of one process in the manufacturing method for the radiation detection module according to the present embodiment.

FIG. 10D is a cross-sectional view of one process in the manufacturing method for the radiation detection module according to the present embodiment.

FIG. 10E is a cross-sectional view of one process in the manufacturing method for the radiation detection module according to the present embodiment.

FIG. 11 is a cross-sectional view of one process in the manufacturing method for the radiation detection module according to the present embodiment.

### DESCRIPTION OF EMBODIMENTS

An embodiment of the disclosure will be described below with reference to the drawings. The disclosure is not limited to the following embodiment, and appropriate design changes can be made within a scope that satisfies the configuration of the disclosure. Further, in the description below, the same reference signs may be used in common among the different drawings for the same portions or portions having similar functions, and repetitive descriptions related to the portions may be omitted. Further, each configuration described in the embodiment and other embodiments may be combined or modified as appropriate within a range that does not depart from the gist of the disclosure. For ease of explanation, in the drawings, which will be referenced below, the configuration may be simplified or schematically illustrated, or some of the constituent members may be omitted. Dimensional ratios between the constituent members illustrated in each of the drawings are not necessarily indicative of actual dimensional ratios. A “row direction” means a horizontal direction of a screen of a display device, and a “column direction” means a vertical direction of the screen of the display device.

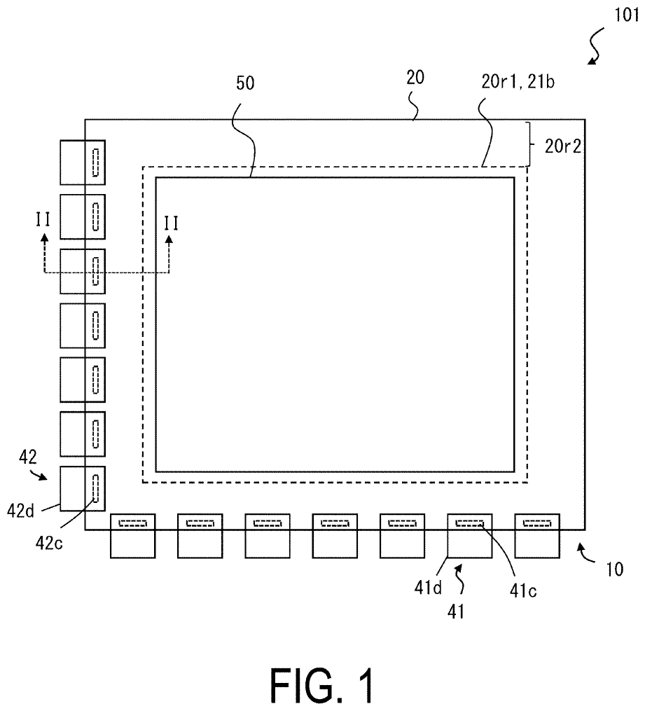

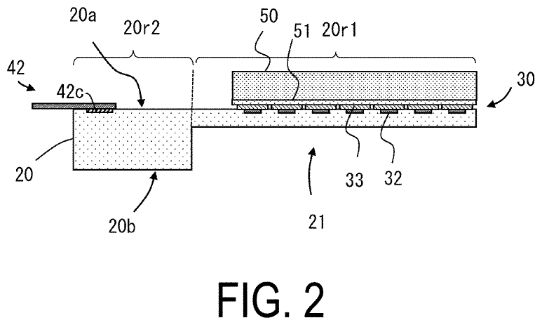

A radiation detection module according to the disclosure is used for an X-ray photographing apparatus using radioactive rays such as X-rays, or an X-ray FPD to be used for X-ray photographing, for example. FIG. 1 is a plan view of a radiation detection module 101 according to the present embodiment, and FIG. 2 illustrates a cross section of the radiation detection module taken along a line II-II in FIG. 1.

The radiation detection module 101 includes an active matrix substrate 10 and a scintillator 50. Additionally, the active matrix substrate 10 includes a support substrate 20 and a pixel array 30 including a plurality of pixels.

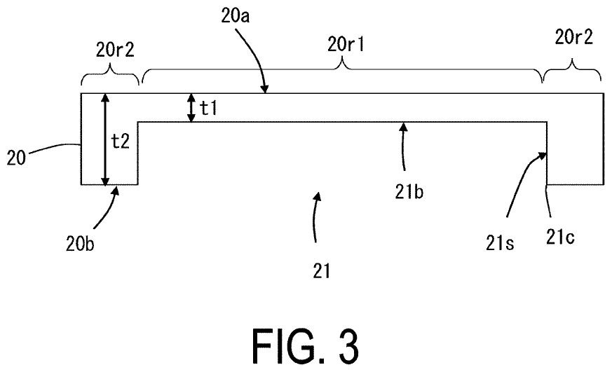

The pixel array 30 is formed on the support substrate 20. FIG. 3 is a cross-sectional view of the radiation detection module 101 taken along a line II-II in FIG. 1.

The support substrate 20 includes a first main surface 20a and a second main surface 20b positioned at the opposite side to the first main surface. As will be described later, the second main surface 20b is a radiation incident surface of the radiation detection module 101. The first main surface 20a includes a first region 20r1 including the center of the first main surface 20a, the first region 20r1 being positioned at the center of the first main surface 20a, and a second region 20r2 positioned around the first region 20r1.

The first region 20r1 has, for example, a rectangular shape, and the pixel array 30 is positioned in the first region 20r1. The second region 20r2 surrounds the first region 20r1, and is positioned along the outer periphery of the first main surface 20a. It is preferable that the second region 20r2 continuously surround the first region 20r1 without a break.

The support substrate 20 includes a recessed portion 21 in a region of the second main surface 20b corresponding to the first region 20r1. By providing the recessed portion 21, a thickness t1 of the support substrate 20 in the first region 20r1 is smaller than a thickness t2 of the support substrate 20 in the second region 20r2. The thickness t1 is preferably equal to or less than ½ of the thickness t2, and is more preferably equal to or less than ⅓ of the thickness t2. The recessed portion 21 can be formed by wet etching, dry etching, sand blasting, mechanical grinding or polishing, as described later.

The recessed portion 21 includes a bottom portion 21b. When viewed in a plan view, that is, when viewed from a direction perpendicular to the first main surface 20a or the second main surface 20b of the support substrate 20, the bottom portion 21b overlaps the first region 20r1, and an outer edge of the bottom portion 21b and an outer edge of the first region 20r1 coincide with each other. In the examples illustrated in FIG. 1 to FIG. 3, the four corners of the rectangular shape of the bottom portion 21b and the first region 20r1 are indicated by ideal points (vertices). However, the corners of the rectangular shape may be rounded, and do not need to have distinct vertices.

In FIG. 3, four side surfaces 21s of the recessed portion 21 are perpendicular to the second main surface 20b, but one or a plurality of side surfaces 21s may be inclined with respect to the second main surface 20b at an angle other than 90°. For example, the side surface 21s may be inclined to face an opening 21c of the recessed portion 21. In this case, the opening 21c is larger than the bottom portion 21b of the recessed portion 21. The one or the plurality of side surfaces 21s may be inclined to face the bottom portion 21b of the recessed portion 21.

A size of the support substrate 20 is determined according to the application and specifications of a radiation FPD manufactured by using the radiation detection module 101. For example, the support substrate 20 has a rectangular shape with a vertical length of 50 mm to 500 mm and a horizontal length of 50 mm to 500 mm, and the first region 20r1 has a rectangular shape with a vertical length of 50 mm to 430 mm and a horizontal length of 50 mm to 430 mm. Additionally, a width w of the second region is from 5 mm to 50 mm. The thickness t1 of the support substrate 20 in the first region 20r1 is, for example, from 0.05 mm to 0.3 mm. Additionally, the thickness t2 in the second region 20r2 is, for example, 0.4 mm to 0.7 mm.

The support substrate 20 is preferably made of an insulating material that hardly absorbs radiation to be detected. For example, the support substrate 20 may be a glass substrate to be used for a liquid crystal display panel.

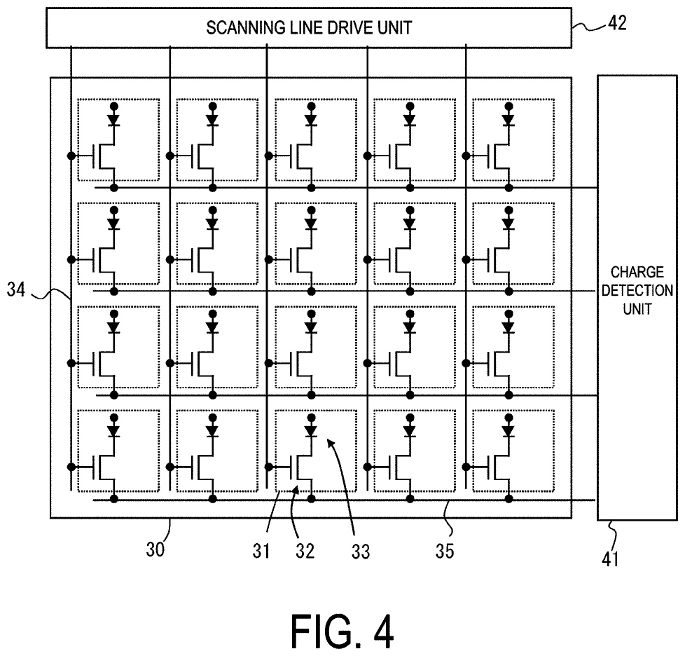

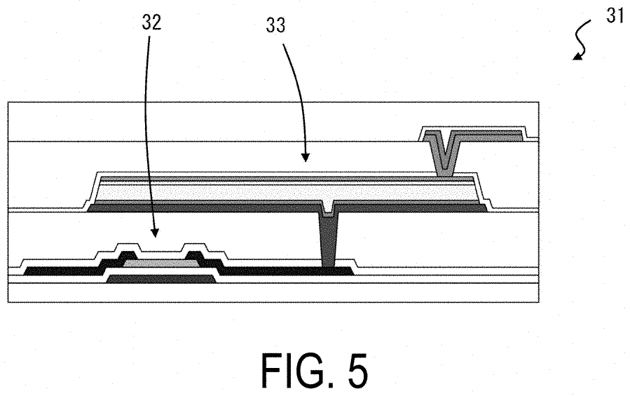

The pixel array 30 is disposed in the first region 20r1 of the support substrate 20. FIG. 4 is a schematic circuit diagram illustrating an example of a circuit configuration of the pixel array 30, and FIG. 5 is a cross-sectional view illustrating an example of a structure of one pixel 31 included in the pixel array 30.

The pixel array 30 includes a plurality of pixels 31 one-dimensionally or two-dimensionally arrayed. In the present embodiment, the plurality of pixels 31 are two-dimensionally arranged in the row direction and the column direction. Each of the pixels 31 includes a switching element and a photoelectric conversion element electrically connected to the switching element. The switching element is, for example, an active element such as an MIM element, a TFT or the like, and in the present embodiment, the pixel 31 includes a TFT 32. The TFT 32 includes, for example, an oxide semiconductor layer containing at least one element selected from the group consisting of In, Ga, and Zn, or a Si-semiconductor layer. The oxide semiconductor layer and the Si semiconductor layer may have various types of crystallinity such as polycrystal, microcrystal, a c-axis orientation distribution or the like.

The photoelectric conversion element receives scintillation light emitted from a scintillator, which will be described later, and generates charges by photoelectric conversion. The photoelectric conversion element is, for example, an element including a semiconductor layer and having various structures capable of separating a hole-electron pair generated by a photon incident on the semiconductor layer. In the present embodiment, the pixel 31 includes a photodiode 33. The photodiode 33 includes, for example, an i-type Si semiconductor layer, and a p-type Si semiconductor layer and an n-type Si semiconductor layer that sandwich the i-type Si semiconductor layer. The pixel 31 may further include an amplifier circuit that amplifies charges generated in the photodiode 33.

The pixel array 30 includes a plurality of scanning lines 34 and a plurality of data lines 35. For example, the gates of the TFTs 32 of a plurality of pixels 31 arranged in the column direction are connected to one scanning line 34. In addition, the sources of the TFTs 32 of the plurality of pixels 31 arranged in the column direction are connected to one data line 35.

In the pixel array 30, various insulating layers and interlayer insulating films are disposed between constituent elements that need to be electrically separated, such as the TFT 32, the photodiode 33, the scanning line 34, the data line 35 and the like. These insulating layers and interlayer insulating films are not illustrated in FIG. 2 and the like. For this reason, although FIG. 2 and the like illustrate that the TFTs 32 are disposed in the support substrate 20, each of the constituent elements of the pixel array 30 is mainly disposed on the first main surface 20a of the support substrate 20.

The radiation detection module 101 further includes a scanning line drive unit 42 that is a driver of the pixel array 30 and a charge detection unit 41. The scanning line drive unit 42 includes substrates 42d and terminals 42c individually provided on the substrates 42d, and drive circuits for sequentially selecting the plurality of scanning lines 34 are formed on the substrates 42d. A portion of the substrate 42d including at least the terminal 42c is positioned in the second region 20r2, and is supported by the support substrate 20. The scanning line drive unit 42 is connected to the scanning lines 34 via the terminals 42c, and is electrically connected to the TFTs 32 of the plurality of pixels 31. Although the scanning line drive unit 42 is divided into two or more substrates in the present embodiment, the scanning line drive unit 42 may be formed on one substrate.

Similarly, the charge detection unit 41 includes substrates 41d and terminals 41c individually provided on the substrates 41d, and charge detection circuits for receiving charges accumulated in the photodiodes 33 and converting the charges into electric signals are formed on the substrates 41d. A portion of the substrate 41d including at least the terminal 41c is positioned in the second region 20r2, and is supported by the support substrate 20. The charge detection unit 41 is connected to the data lines 35 via the terminals 41c, and is electrically connected to the TFTs 32 of the plurality of pixels 31. In the present embodiment, the charge detection unit 41 is divided into two or more substrates, but the charge detection unit 41 may be formed on one substrate.

The scintillator 50 emits scintillation light when radiation transmitted through a body or an object is incident thereon. The scintillator 50 covers the photodiodes 33 that are photoelectric conversion elements of the plurality of pixels 31. For example, the scintillator 50 has a sheet shape, and is bonded to the plurality of pixels 31 with an adhesive layer 51 such as an OCA interposed therebetween. The scintillator 50 may be a vapor deposition film.

The scintillator 50 is made of a material corresponding to radiation to be used. The radiation may be X-rays, α-rays, γ-rays, or the like. X-rays are widely used for a medical or industrial radiation FPD. As the scintillator 50 that detects X-rays, a single crystal or polycrystal material such as Thallium activated Cesium Iodide (Tl:CsI), Gadolinium OxySulfide (GOS) or the like can be used.

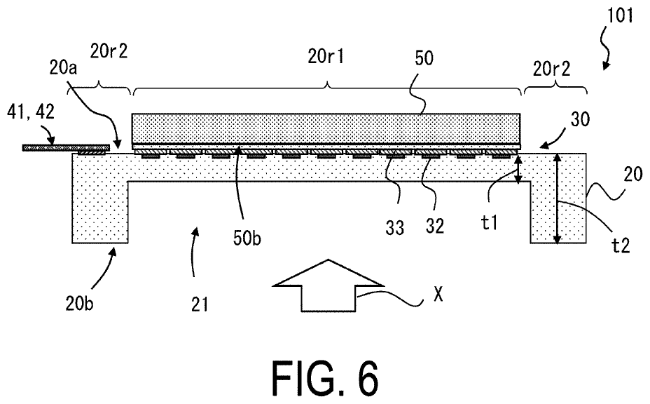

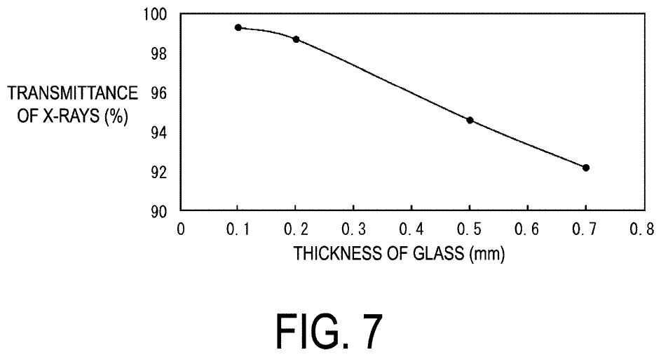

An operation of the radiation detection module 101 will be described with reference to FIG. 6 and FIG. 7. As illustrated in FIG. 6, when radiation is detected by the radiation detection module 101, radiation X transmitted through a body or an object is caused to be incident on the second main surface 20b side of the support substrate 20. The radiation X transmits through the support substrate 20 and the pixel array 30 formed on the first main surface 20a, and is incident on the scintillator 50 from the second main surface 50b adjacent to the photodiodes 33. The radiation X incident on the scintillator 50 excites a substance constituting the scintillator 50, and scintillation light is emitted from the scintillator 50. The photodiode 33 detects the generated scintillation light and generates charges by photoelectric conversion. The charges generated by the photodiode 33 in each pixel 31 are converted into an electric signal by the charge detection unit 41 in a reading order controlled by the scanning line drive unit 42. Since the radiation incident on the radiation detection module 101 is partially attenuated by the body or the object through which the radiation has been transmitted, the radiation has a two-dimensional intensity distribution, and an image based on the generated electric signals also has a two-dimensional distribution corresponding to the body or the object.

According to the radiation detection module 101 of the present embodiment, the radiation X is made incident on the scintillator 50 from the second main surface 50b adjacent to the photodiodes 33. Thus, the generated scintillation light is incident on the photodiodes 33 without transmitting through the scintillator 50 in the thickness direction. Thus, attenuation or diffusion of the scintillation light in the scintillator 50 can be suppressed, and a radiation image with high sensitivity and high resolution can be acquired.

In a radiation FPD employing such a detection method, it is necessary to transmit radiation through a support substrate that supports a pixel array. The radiation detection module 101 according to the present embodiment can suppress attenuation of radiation at the support substrate 20, because the support substrate 20 has the small thickness t1 in the first region 20r1 where the pixel array 30 is positioned. Thus, the radiation can be detected with high sensitivity.

In addition, since the thickness t2 in the second region 20r2 that is the outer peripheral portion of the support substrate 20 is large, it is possible to secure the strength of the support substrate 20 while reducing the thickness t1 in the first region 20r1. Further, the drivers of the active matrix substrate 10 such as the charge detection unit 41, the scanning line drive unit 42 and the like are connected to the pixel array 30 in the second region 20r2 of the support substrate 20. For this reason, even when stresses are applied to the support substrate 20 from the outside through the substrates of the drivers and the connection terminals, since the thickness in the second region 20r2 of the support substrate 20 is large, deformation or damage of the support substrate 20 is suppressed.

FIG. 7 shows an example of measurement results of a transmittance of transmitted X-rays when the thickness of the glass substrate is varied. An X-ray tube for medical use was used as a radiation source, and X-rays were irradiated at a 70 kV energy. Further, aluminoborosilicate glass was used for the glass substrate.

When the thicknesses of the glass substrates were 0.1, 0.2, 0.5, and 0.7 mm, the transmittances were 99.3, 98.7, 94.6, and 92.2%, respectively, as compared with the case where no glass substrate was provided. This indicates that attenuation of X-rays at the support substrate 20 can be suppressed and X-rays with high intensity can be incident on the scintillator 50 by reducing the thickness of the support substrate 20.

On the other hand, according to the radiation detection module 101 of the present embodiment, the support substrate 20 is thicker in the second region 20r2 around the first region 20r1. Thus, it is possible to ensure the strength of the support substrate 20 and to suppress cracking or chipping of the support substrate 20 during manufacturing of the radiation detection module 101 or during manufacturing of an FPD with the completed radiation detection module. In addition, handling of the radiation detection module 101 during these processes can be facilitated.

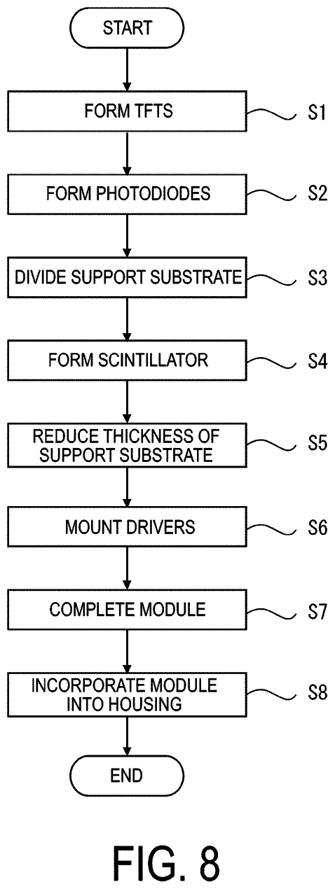

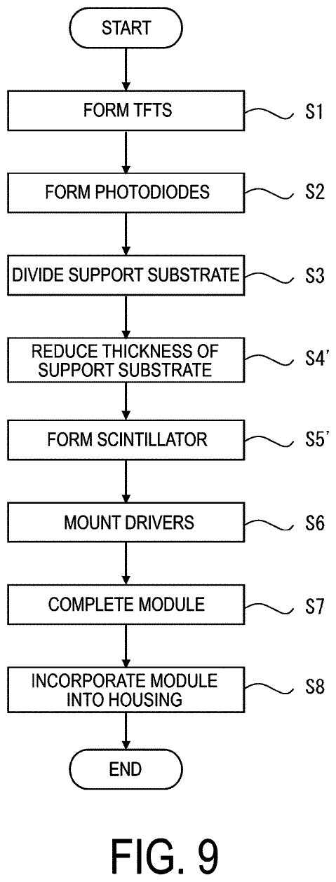

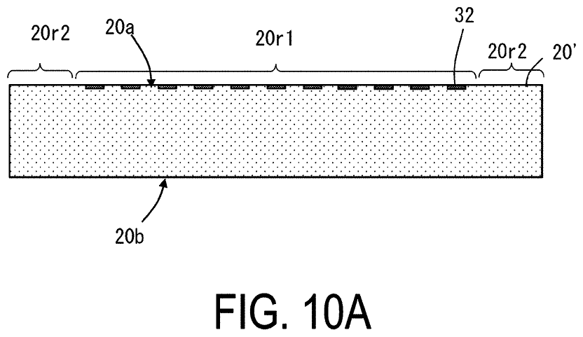

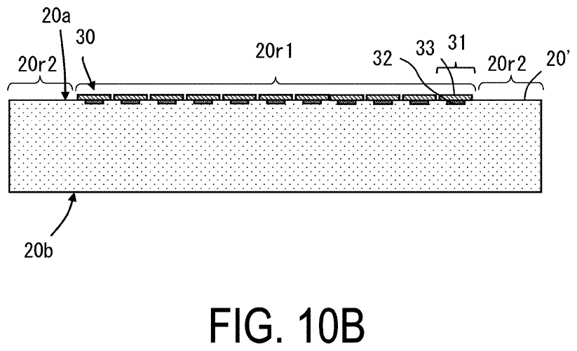

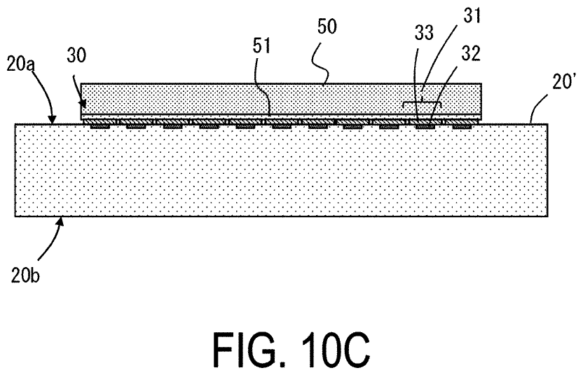

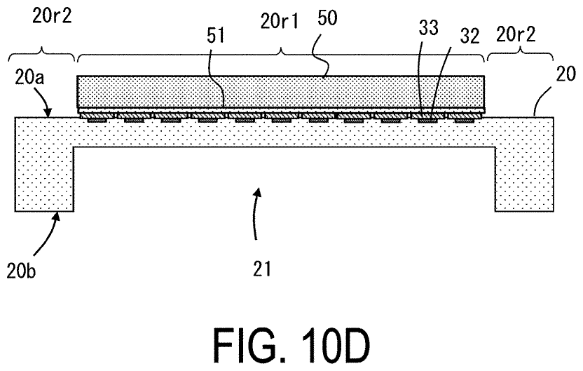

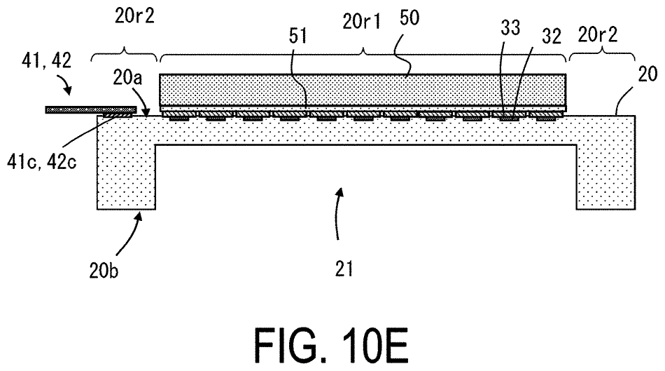

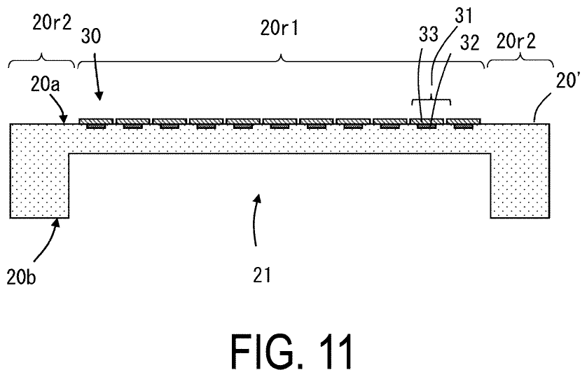

Next, a manufacturing method for the radiation detection module 101 will be described. FIG. 8 and FIG. 9 are flowcharts illustrating the manufacturing method for the radiation detection module 101. Additionally, FIG. 10A to FIG. 10E and FIG. 11 are cross-sectional views of processes of the manufacturing method for the radiation detection module 101.

The manufacturing method for the radiation detection module 101 according to the present embodiment includes a process (A) of forming a plurality of pixels on a support substrate and a process (B) of removing a part of the support substrate from a second main surface. In addition, a process (C) of disposing the scintillator and a process (D) of mounting the drivers are further included. Each process will be described in detail below.

### (1) Process (A) of Forming Plurality of Pixels on Support Substrate

As illustrated in FIG. 10A, a support substrate 20′ is prepared. The support substrate 20′ includes a first main surface 20a and a second main surface 20b positioned at the opposite side to the first main surface 20a. The first main surface includes a first region 20r1 including a central portion and a second region 20r2 surrounding the first region 20r1.

First, the pixel array 30 including the plurality of pixels 31 is formed on the first main surface 20a of the support substrate 20′ (S1, S2). To be specific, for example, a plurality of TFTs 32 are formed in the first region 20r1 of the first main surface 20a of the support substrate 20′ by using a semiconductor manufacturing technique to be used for a liquid crystal display device (S1). Further, as illustrated in FIG. 10B, the photodiodes 33 connected to the plurality of TFTs 32 are formed (S2). Thereafter, in a case where the support substrate 20′ is an aggregate substrate corresponding to a plurality of radiation detection modules 101, the support substrate 20′ is divided to have the size of the substrate of each radiation detection module 101 (S3).

### (2) Process (C) of Disposing Scintillator

As illustrated in FIG. 10C, the scintillator 50 covers the photodiodes 33 of the plurality of pixels 31. For example, the scintillator 50 having a sheet shape such as a GOS sheet, a CsI sheet and the like is prepared, and the scintillator 50 is bonded to the photodiodes 33 with the adhesive layer 51 interposed therebetween (S4). When a vapor deposition film is used as the scintillator 50, for example, a vapor deposition film of CsI may be deposited on the photodiodes 33 of the plurality of pixels 31 by a vacuum vapor deposition technique.

(3) Process (B) of Removing Part of Support Substrate from Second Main Surface

As illustrated in FIG. 10D, a part of the support substrate 20′ is removed from the second main surface 20b to form the recessed portion 21 in a region of the second main surface 20b corresponding to the first region 20r1 (S5). For example, on the second main surface 20b, a mask including an opening at a position and in a shape corresponding to those of the first region 20r1 is formed by using a resist or the like. Thereafter, a part of the support substrate 20′ is removed by wet etching, dry etching, or sand blasting to form the recessed portion 21 at the second main surface 20b. When the support substrate is a glass substrate, an etching solution such as hydrofluoric acid can be used for the wet etching. In addition, for the dry etching, a gas such as a fluorine gas can be used. Alternatively, the recessed portion 21 may be formed by removing a part of the support substrate 20′ by using a grinding apparatus for a semiconductor wafer or a polishing apparatus for planarization to be used in manufacturing a semiconductor device. As a result, the support substrate 20 that is thinner in the first region 20r1 than in the second region 20r2 can be obtained.

### (4) Process (D) of Mounting Drivers

The charge detection unit 41 and the scanning line drive unit 42 are prepared, and the scanning line drive unit and the charge detection unit are mounted in the second region 20r2 of the first main surface 20a of the support substrate 20 (S6). As illustrated in FIG. 10E, the terminals 41c of the charge detection unit 41 and the terminals 42c of the scanning line drive unit 42 are electrically connected to the plurality of scanning lines 34 and the plurality of data lines 35 in the second region 20r2 of the support substrate 20. Since the terminals 41c and 42c are connected to the second region 20r2 that is thicker than the first region 20r1, it is possible to ensure the strength of a pressing force applied to the support substrate 20 from above when these drivers are connected. Due to this, the charge detection unit 41 and the scanning line drive unit 42 are electrically connected to the TFTs 32 of the plurality of pixels 31. Thus, the radiation detection module 101 is completed (S7).

(5) Incorporation into Housing

Thereafter, the radiation detection module 101 is incorporated into a housing to complete the radiation FPD.

According to the manufacturing method for the radiation detection module 101 of the present embodiment, after the pixel array 30 is formed on the support substrate 20′ and the scintillator 50 is disposed, a part of the support substrate 20′ is removed. Thus, when the pixel array 30 is formed and the scintillator 50 is disposed, cracking or chipping of the support substrate 20′ is suppressed. In addition, since the support substrate has a uniform thickness in forming the pixel array 30, even when the support substrate 20′ is heated and cooled in forming the pixel array 30, the entire support substrate 20′ uniformly expands and contracts, and thus, deformation of the support substrate 20′ and generation of stress in the structure of the pixel array 30 to be formed are suppressed.

In addition, since the thickness of the support substrate 20 where the recessed portion 21 is formed is large in the second region 20r2, an appropriate mechanical strength is secured even when the charge detection unit 41 and the scanning line drive unit 42 are mounted, and cracking or chipping of the support substrate 20 is suppressed.

Note that in the embodiment described above, a part of the support substrate is removed after the scintillator 50 is formed. However, when the scintillator 50 having a sheet shape is used, the part of the support substrate may be removed after the scintillator 50 is formed. To be more specific, as illustrated in FIG. 9 and FIG. 11, the part of the support substrate 20′ may be removed from the second main surface 20b after the photodiodes 33 is formed in the first region 20r1 to form a recessed portion in a region of the second main surface 20b corresponding to the first region 20r1 (S4′). Thereafter, the scintillator 50 may cover the photodiodes 33 of the plurality of pixels 31 (S5′). In this case, it is preferable to use a scintillator having a sheet shape for forming the scintillator 50.

The radiation detection module and the manufacturing method for the radiation detection module of the disclosure are not limited to the above-described embodiment, and various modifications are possible. For example, the shapes of the support substrate 20 and the recessed portion 21, the circuit configuration of the pixel array, and the like are not limited to those in the above-described embodiment. In addition, in the manufacturing method for the radiation detection module, a plurality of processes may be performed in combination, or conversely, one process may be divided into two or more processes.

The radiation detection module and the manufacturing method for the radiation detection module of the disclosure can also be described as follows.

A radiation detection module according to a first configuration includes an active matrix substrate and a scintillator. The active matrix substrate includes a support substrate including a first main surface and a second main surface positioned at an opposite side to the first main surface, the first main surface including a first region and a second region surrounding the first region, and a plurality of pixels one-dimensionally or two-dimensionally arrayed in the first region of the first main surface, the plurality of pixels each of which includes a switching element and a photoelectric conversion element electrically connected to the switching element. The scintillator covers the photoelectric conversion elements of the plurality of pixels. A thickness of the support substrate in the first region is smaller than a thickness in the second region.

With the radiation detection module according to the first configuration, when radiation is made incident from the second main surface, scintillation light is incident on the photoelectric conversion element without being transmitted through the scintillator in a thickness direction. Thus, attenuation and diffusion of the scintillation light in the scintillator are suppressed, and it is possible to acquire a radiation image with high sensitivity and high resolution. In addition, since the thickness of the support substrate is small in the first region where the plurality of pixels are positioned, attenuation of the radiation at the support substrate is suppressed, and high detection sensitivity of the radiation can be achieved. In addition, since a thickness of the second region 20r2 that is an outer peripheral portion of the support substrate is large, it is possible to ensure the strength of the entire support substrate while making the thickness of the first region small.

In a radiation detection module according to a second configuration, in the first configuration, the second region may be positioned along an outer periphery of the first main surface of the support substrate.

In a radiation detection module according to a third configuration, in the first or second configuration, the thickness of the support substrate in the first region may be equal to or less than ½ of the thickness of the support substrate in the second region.

In a radiation detection module according to a fourth configuration, in the first to third configurations, the support substrate may include a recessed portion in a region of the second main surface corresponding to the first region.

A radiation detection module according to a fifth configuration, in the first to fourth configurations, may further include a scanning line drive unit electrically connected to the switching elements of the plurality of pixels, and a charge detection unit electrically connected to the switching elements of the plurality of pixels, and at least a part of the scanning line drive unit and at least a part of the charge detection unit may be positioned in the second region of the first main surface of the support substrate. Since at least the part of the scanning line drive unit and at least the part of the charge detection unit are disposed in the second region of the support substrate, even when stress is applied to the support substrate 20 from the outside via substrates and connection terminals of the scanning line drive unit and the charge detection unit, deformation or damage of the support substrate is suppressed.

In a radiation detection module according to a sixth configuration, in the first to fifth configurations, the second main surface of the support substrate may be a radiation incident surface.

In a radiation detection module according to a seventh configuration, in the first to sixth configurations, each of the plurality of pixels may further include an amplifier circuit configured to amplify charges generated by the photoelectric conversion element.

A manufacturing method for a radiation detection module according to an eighth configuration includes (A) forming a plurality of pixels each of which includes a switching element and a photoelectric conversion element in a first region of a support substrate including a first main surface and a second main surface positioned at an opposite side to the first main surface, the first main surface including the first region and a second region surrounding the first region, and (B) removing a part of the support substrate from the second main surface and then forming a recessed portion in a region of the second main surface corresponding to the first region, and making a thickness of the support substrate in the first region smaller than a thickness of the support substrate in the second region.

The manufacturing method for the radiation detection module according to the eighth configuration suppresses cracking or chipping of the support substrate in forming a pixel array and disposing a scintillator. In addition, since the support substrate has a uniform thickness when the pixel array is formed, even when the support substrate is heated and cooled when the pixel array is formed, the entire support substrate uniformly expands and contracts, and deformation of the support substrate and generation of stress in the structure of the pixel array to be formed are suppressed.

A manufacturing method for a radiation detection module according to a ninth configuration may further include, in the eighth configuration, (C) disposing a scintillator that covers the photoelectric conversion elements of the plurality of pixels before (B).

A manufacturing method for a radiation detection module according to a tenth configuration may further include, in the eighth configuration, (C) disposing a scintillator that covers the photoelectric conversion elements of the plurality of pixels after (B).

In a manufacturing method for a radiation detection module according to an eleventh configuration, in the ninth or tenth configuration, in (C), the scintillator may have a sheet shape, and the scintillator having the sheet shape may be bonded to the plurality of pixels with an adhesive layer interposed between the scintillator and the plurality of pixels.

In a manufacturing method for a radiation detection module according to a twelfth configuration, in the ninth configuration, in (C), a material of the scintillator may be deposited on the plurality of pixels by vapor deposition and then the scintillator may be formed.

A manufacturing method for a radiation detection module according to a thirteenth configuration may further include, in the eighth to tenth configurations, after (B), (D) mounting a scanning line drive unit and a charge detection unit in the second region of the first main surface of the support substrate and electrically connecting the scanning line drive unit and the charge detection unit to the switching elements of the plurality of pixels. Since the charge detection unit and the scanning line drive unit are disposed in the second region of the support substrate, deformation or damage of the support substrate is suppressed when the charge detection unit and the scanning line drive unit are mounted.

### INDUSTRIAL APPLICABILITY

The radiation detection module and the manufacturing method for the radiation detection module according to the disclosure can be suitably used in various fields, and are suitably used for a medical X-ray FPD or the like.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

1. A radiation detection module comprising:
an active matrix substrate including
a support substrate including a first main surface and a second main surface positioned at an opposite side to the first main surface, the first main surface including a first region and a second region surrounding the first region, and
a plurality of pixels one-dimensionally or two-dimensionally arrayed in the first region of the first main surface, the plurality of pixels each of which includes a switching element and a photoelectric conversion element electrically connected to the switching element; and
a scintillator covering the photoelectric conversion elements of the plurality of pixels, wherein
a thickness of the support substrate in the first region is smaller than a thickness of the support substrate in the second region.

2. The radiation detection module according to claim 1,
wherein the second region is positioned along an outer periphery of the first main surface of the support substrate.

3. The radiation detection module according to claim 1,
wherein the thickness of the support substrate in the first region is equal to or less than ½ of the thickness of the support substrate in the second region.

4. The radiation detection module according to claim 1,
wherein the support substrate includes a recessed portion in a region of the second main surface corresponding to the first region.

5. The radiation detection module according to claim 1, the radiation detection module further comprising:
a scanning line drive unit electrically connected to the switching elements of the plurality of pixels; and
a charge detection unit electrically connected to the switching elements of the plurality of pixels, wherein
at least a part of the scanning line drive unit and at least a part of the charge detection unit are positioned in the second region of the first main surface of the support substrate.

6. The radiation detection module according to claim 1,
wherein the second main surface of the support substrate is a radiation incident surface.

7. The radiation detection module according to claim 1,
wherein each of the plurality of pixels further includes an amplifier circuit configured to amplify charges generated by the photoelectric conversion element.

8. A manufacturing method for a radiation detection module, the manufacturing method comprising:
(A) forming a plurality of pixels each of which includes a switching element and a photoelectric conversion element in a first region of a support substrate including a first main surface and a second main surface positioned at an opposite side to the first main surface, the first main surface including the first region and a second region surrounding the first region; and
(B) removing a part of the support substrate from the second main surface and then forming a recessed portion in a region of the second main surface corresponding to the first region, and making a thickness of the support substrate in the first region smaller than a thickness of the support substrate in the second region.

9. The manufacturing method for the radiation detection module according to claim 8, the manufacturing method further comprising:
(C) disposing a scintillator that covers the photoelectric conversion elements of the plurality of pixels before (B).

10. The manufacturing method for the radiation detection module according to claim 8, the manufacturing method further comprising:
(C) disposing a scintillator that covers the photoelectric conversion elements of the plurality of pixels after (B).

11. The manufacturing method for the radiation detection module according to claim 9,
wherein, in (C), the scintillator has a sheet shape, and the scintillator having the sheet shape is bonded to the plurality of pixels with an adhesive layer interposed between the scintillator and the plurality of pixels.

12. The manufacturing method for the radiation detection module according to claim 9,
wherein, in (C), a material of the scintillator is deposited on the plurality of pixels by vapor deposition and then the scintillator is formed.

13. The manufacturing method for the radiation detection module according to claim 8, further comprising:
after (B), (D) mounting a scanning line drive unit and a charge detection unit in the second region of the first main surface of the support substrate, and electrically connecting the scanning line drive unit and the charge detection unit to the switching elements of the plurality of pixels.
